(19) United States
(12) Patent Application Publication
(10) Pub. No.: US 2010/0173445 A1
(43) Pub. Date: Jul. 8, 2010

(54) PRODUCTION METHOD FOR A SENSOR UNIT OF AN X-RAY DETECTOR

(76) Inventors: Ludwig Danzer, Wendelstein (DE); Michael Miess, Baiersdorf (DE); Stefan Wirth, Erlangen (DE)

Correspondence Address: HARNESS, DICKEY & PIERCE, P.L.C., P.O.BOX 8910, RESTON, VA, 20195, US

(21) Appl. No.: 12/649,386

(22) Filed: Dec. 30, 2009

(30) Foreign Application Priority Data
Jan. 8, 2009 (DE) 10 2009 004 120.6

(51) Int. Cl. H01L 31/18

(52) U.S. Cl. 438/69; 257/E31.127

(57) ABSTRACT

A production method for a sensor unit of an X-ray detector is disclosed, which can be implemented easily and precisely, is specified, the sensor unit including a scintillator with photodiodes integrated in its septa for lateral readout. In at least one embodiment of the method, individual scintillator strips are initially produced from a plurality of scintillator pixels adjoining one another along one dimension. Respectively one photodiode strip, made of a plurality of photodiodes in turn adjoining one another along one dimension, is attached to each of the individual scintillator strips along a longitudinal side in order to form a sensor strip. Here, respectively one photodiode is associated with each scintillator pixel for readout purposes. Finally, a plurality of such sensor strips are interconnected to form the two-dimensional sensor unit such that a longitudinal side of the one sensor strip facing away from the photodiode strip respectively rests against a rear side of the photodiode strip of the adjacent sensor strip.

### PRIORITY STATEMENT

The present application hereby claims priority under 35 U.S.C. §119 on German patent application number DE 10 2009 004 120.6 filed Jan. 8, 2009, the entire contents of which are hereby incorporated herein by reference.

### FIELD

At least one embodiment of the invention generally relates to a production method for a sensor unit of an X-ray detector, in particular for a computed tomography scanner.

### BACKGROUND

A computed tomography scanner (CT) usually comprises a so-called gantry, with an X-ray beam source (X-ray tube) and a radially opposite (X-ray) detector being attached thereto. The gantry is intended to rotate around an object to be irradiated, with the X-ray radiation emitted and modified during the penetration of the object being detected by the detector.

The detector is generally assembled from a plurality of individual detector modules. Each detector module comprises a sensor unit which is in turn formed from a scintillator for converting the X-ray radiation into visible light and photodiodes for detecting this light. The scintillator is normally formed from a plurality of scintillator pixels, usually in the form of cubic elements of scintillating material. The scintillator pixels are generally arranged in an array, that is to say in a matrix arranged in a checkerboard fashion in rows and columns. Narrow interspaces (so-called septa), filled with a light reflecting and/or absorbing material, are in each case formed between the individual pixels; these septa are used to delimit the individual pixels in respect of one another in terms of radiation.

A method for producing such a scintillator is disclosed in, for example, DE 198 49 772 A1. Accordingly, elongate scintillator elements are firstly layered next to and above one another in parallel and bonded to form a block whilst forming the septa. Subsequently, the block is cut into slices, transversely with respect to the longitudinal direction of extent of the scintillator elements, such that the individual slices have the desired array structure.

Within the scope of the sensor unit, each scintillator pixel has one photodiode associated with it. In a conventional sensor unit—as is described, for example, in DE 10 2005 014 187 A1—these photodiodes are arranged in an array matched to the pixel structure of the scintillator, with the array being fitted to the outer side of the scintillator facing away from the X-ray tube.

The individual sensor units are often arranged in a single row on an arc of the gantry opposite to the X-ray tube. So as to cover an area which is as large as possible during the detection of the X-ray radiation—and thus reduce the examination time and hence the radiation exposure of the patient—provision is sometimes made for the individual sensor units to be conjoined in a plurality of rows (adjacent to one another in the axial direction of the gantry) to form a partial cylinder surface.

In general, each detector module furthermore in each case comprises a printed circuit board with signal-processing readout electronics for contacting the photodiodes. However, the requirements in terms of area of the readout electronics are usually significantly greater than the respectively assigned sensor surface. Particularly in the case of a large-area detector, the electrical contacting of the photodiodes is problematic because there is no space laterally due to the adjacent additional sensor units or due to the additional detector modules.

By way of example, a solution to this problem comprises designing the detector modules in a vertical fashion, with the readout electronics intended to stick out at right angles from the outer side of the sensor unit facing away from the X-ray tube.

In this context, a sensor unit in which, as proposed in WO 2006/114716 A2, the photodiodes are aligned in an upright fashion and are integrated into the septa of the scintillator in rows is particularly advantageous. In the process, the visible light emanating from the individual scintillator pixels is detected to the side of the scintillator pixels. The readout electronics can then contact the photodiodes relatively easily on the outer side of the scintillator or the sensor unit.

However, assembling the photodiodes in the septa of the scintillator array has proven to be very difficult.

### SUMMARY

In at least one embodiment of the invention, a production method is specified for a sensor unit of an X-ray detector, which can be performed easily and precisely and comprises a scintillator with photodiodes integrated into the septa for lateral readout.

In the process of at least one embodiment, individual scintillator strips are firstly produced from a plurality of scintillator pixels adjoining one another along one dimension. A photodiode strip, made of a plurality of photodiodes in turn adjoining one another along one dimension, is in each case attached (in particular adhesively bonded) to a longitudinal side of each of the individual scintillator strips. Here, respectively one photodiode is arranged adjoining respectively one scintillator pixel for readout purposes. The combination of scintillator strips and photodiode strips is referred to as a sensor strip in the following text. Finally, a plurality of such sensor strips are interconnected to form the two-dimensional sensor unit such that a longitudinal side of the one sensor strip facing away from the photodiode strip respectively rests against a rear side of the photodiode strip of the adjacent sensor strip. In this case, expediently each of the sensor strips respectively has the same number of scintillator pixels. Overall, in an expedient refinement, in the finished scintillator, the scintillator pixels are arranged in an array structure of rows and columns.

Thus, according to at least one embodiment of the invention, provision is made for the scintillator or the sensor unit to be assembled in rows of the sensor strips which are initially present as individual elements.

Since the sensor strips are prefabricated as individual elements, in the process the photodiode strips can also be adjusted with respect to the scintillator strips, and hence the photodiodes can be adjusted with respect to the scintillator pixels, in a particularly simple and precise fashion. In particular, this can advantageously be carried out with the aid of a stop. Moreover, the production of the sensor strips can be automated particularly well. Furthermore, in the process, there is no, or only very little, risk of damaging the light-sensitive surface of the photodiodes.

Furthermore, in the case of a sensor strip which is present as a single element, the photodiodes are particularly easily accessible. Thus, advantageously, both the stability of the connection between the photodiode strip and scintillator strip and the functionality thereof can be checked separately for each sensor strip.

As a result, this advantageously produces comparatively little waste because it is only a single sensor strip which has to be rejected if the quality is insufficient, whereas a whole scintillator array would have to have been discarded in the case of a scintillator produced as an array from the outset. As a result of this, the production method is comparatively cost-effective. Finally, assembling the individual sensor strips to form the sensor unit can also be automated comparatively well.

In an embodiment of the production method which can be implemented particularly easily, the photodiode strips are adhesively bonded to the scintillator strip using an optically transparent adhesive.

The scintillator strips are preferably made from substantially cube-shaped, in particular dice-shaped, scintillator pixels. In preferred dimensioning, the individual cubes each have edge lengths of approximately 0.5 to 3 mm.

In the process, individual beams of scintillator material are expediently firstly lined up parallel to and at a certain distance from one another in order to produce the scintillator strips. The individual beams are connected to form a palette by filling the interspaces with a light reflecting and/or absorbing material, for example a polymer which is liquid at first. Said palette is subsequently separated out, in particular sawed, into the individual scintillator strips in the transverse direction in respect of the individual beams. Each emerging scintillator strip therefore is subdivided along the length into—cuboid—scintillator pixels delimited in respect of one another.

In an advantageous embodiment of the production method, the sides of each scintillator pixel not intended to adjoin a photodiode are already provided with a reflector lacquer before the sensor strip is produced and thus, possibly, before the scintillator strip is produced as well. Since each scintillator strip is initially available as a separate individual part, the application of the reflector lacquer on the entire side face thereof (and hence on the outside side faces of the scintillator pixels thereof) in particular can be carried out particularly well. As intended, the reflector lacquer reflects the visible light emitted by the individual scintillator pixels. This increases the radiation intensity incident on the photodiode.

In an example embodiment of the production method, provision is made for the individual sensor strips thereof to be produced and assembled such that a narrow side (on the outer side intended to face away from the X-ray tube) provided for contacting the photodiodes of each photodiode strip respectively protrudes beyond the adjacent scintillator strip or strips.

Given preferred dimensions, the height (intended to be viewed along a vertical direction) of the photodiode strips therefore is selected to be greater than the height (likewise viewed in the vertical direction) of the scintillator strips. In the case of a flush arrangement of the photodiode strips and the scintillator strips on the inner side of the scintillator or the sensor unit intended to face the X-ray tube, the narrow sides of the photodiode strips then protrude from the outer side of the sensor unit.

Such a sensor unit is preferably used for a detector in a computed tomography scanner. As a result of being able to contact the photodiodes on the outer side of the scintillator, the described sensor unit is particularly suitable for a flat-panel detector made of a multiplicity of detector modules arranged adjacently to one another, over an area, with a very small spacing (in both a plurality of rows and a plurality of columns).

Here, the electronics of each detector module required for the readout of the photodiodes are preferably arranged in turn in a vertical arrangement—perpendicular with respect to the scintillator surface—on the outer side of the sensor unit, as intended.

### BRIEF DESCRIPTION OF THE DRAWINGS

In the following text, an example embodiment of the invention will be explained in more detail on the basis of a drawing, in which:

FIG. 1 shows a schematic, perspective illustration of a computed tomography scanner with an X-ray detector which comprises a multiplicity of detector modules with respectively one sensor unit,

FIG. 2 shows a perspective illustration of a sensor unit as per FIG. 1 formed from a scintillator and associated photodiodes, and

FIG. 3 and FIG. 4 respectively show in a schematic exploded view, intermediate products which follow one another of a method for producing the sensor unit.

Equivalent parts and dimensions are always provided with the same reference signs in all figures.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

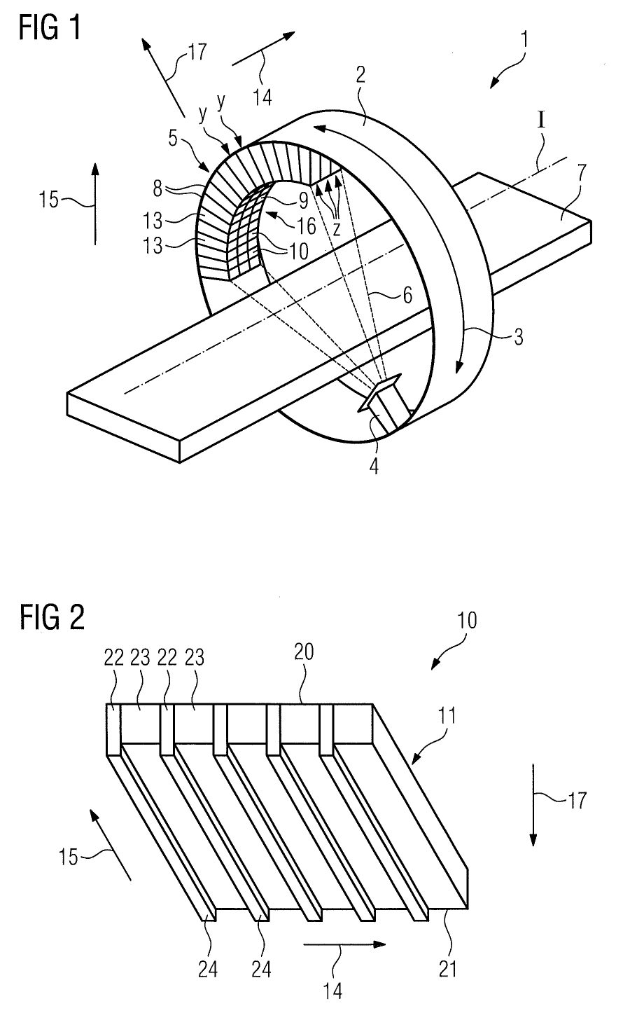

FIG. 1 illustrates a computed tomography scanner 1 in a roughly schematic, simplified illustration.

The computed tomography scanner 1 comprises a basically annular gantry 2 which can rotate about an isocentric axis I of the computed tomography scanner 12 (indicated by a double-headed arrow 3).

Attached to the gantry 2 is, firstly, an X-ray tube 4 and, secondly, a detector 5 for detecting the X-ray radiation 6 emanating from the X-ray tube 4, the detector lying substantially opposite to said X-ray tube.

A patient is, as intended, positioned in the region of the isocentric axis I (within the gantry 2) for irradiation purposes with the aid of a patient couch 7.

The detector 5 is assembled from a multiplicity of basically cube-shaped detector modules 8.

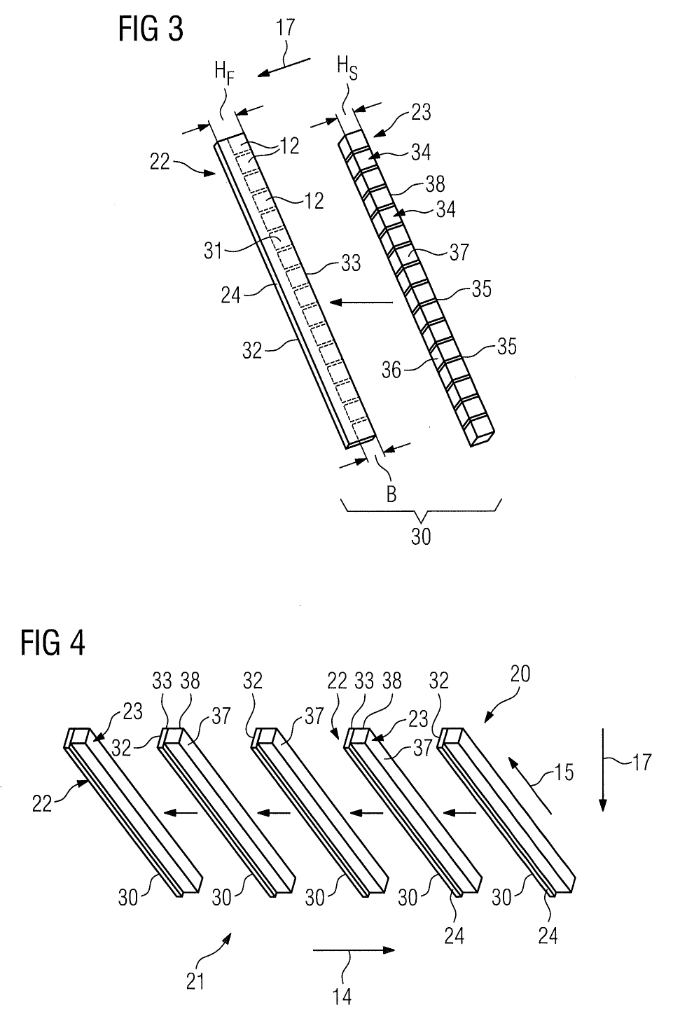

Each detector module 8 firstly comprises a substantially square sensor unit 10 respectively on a top side 9 intended to face the X-ray tube 4, which sensor unit comprises a scintillator 11 (FIG. 2) for converting the X-ray radiation 6 into visible light. A multiplicity of photodiodes 12 (FIG. 3) are integrated into each scintillator 11 for the purpose of detecting the visible light. Secondly, each detector module 8 comprises an elongate electronics unit 13 intended to face away from the X-ray tube 4, which electronics unit inter alfa contacts the photodiodes 12 for readout purposes.

In an assembled state shown in the present illustration, the individual detector modules 8 are, in respect of the gantry 2, fitted adjacent to one another over an area in a plurality of rows Z in an axial direction 14 and in a plurality of columns Y in a tangential direction 15, wherein all sensor units 10 together form a detector area 16. Hence, the detector area 16 sensitive to the X-ray radiation 6 basically covers a partial cylinder surface of the gantry 2.

Each electronics unit 13 is basically aligned along a vertical direction 17 which, in respect of the gantry 2, points radially outward.

FIG. 2 illustrates one of the sensor units 10 separately from the others. For orientation purposes, the vertical direction 17, the axial direction 14 and the tangential direction 15 are illustrated in accordance with the intended installed situation as per FIG. 1. This alignment of the sensor unit 10 has been selected merely by way of example; it is in principle possible for the orientation of the sensor unit 10 to also be turned by 90° or 180° within the detector area 16.

The sensor unit 10 is substantially in the shape of a square plate. The (square) inner side 20 thereof is intended to face the X-ray tube 4, while the outer side 21 thereof opposite thereto is intended to face away from the X-ray tube 4, or face the electronics unit 13.

The sensor unit 10 is assembled from a multiplicity of photodiode strips 22 and scintillator strips 23. In this case, each photodiode strip 22 or each scintillator strip 23 is aligned along the tangential direction 15. In the axial direction 14, the photodiode strips 22 and the scintillator strips 23 are respectively arranged adjacent to one another in an alternating fashion and interconnected. In the process, a narrow side 24 of the photodiode strips 22 respectively protrudes beyond the scintillator strips 23 on the outer side 21 of the sensor unit 10. The photodiodes 12 integrated in the photodiode strip 22 can be contacted by means of the electronics unit 13 on this narrow side 24.

In order to produce the sensor unit 10 as per FIG. 2, the method illustrated on the basis of FIGS. 3 and 4 is applied. In the process, as illustrated in FIG. 3, a photodiode strip 22 and a scintillator strip 23 are initially joined to form a so-called sensor strip 30.

A multiplicity of photodiodes 12 are arranged adjacent to one another on the photodiode strip 22 (along the length thereof). The side of the photodiode strip 22 on which the light-sensitive surfaces of the photodiodes 12 are attached is referred to as the front side 31 thereof. The side of the photodiode strip opposite to the front side is referred to as the rear side 32 of the photodiode strip. On the front side 31, the photodiodes 12 are arranged laterally offset with respect to the longitudinal direction in the region of a narrow side 33, while the narrow side 24 of the photodiode strip opposite thereto has electrical contacts (not illustrated in any more detail) affixed to it for connecting the photodiodes 12 to the electronics unit 13.

The scintillator strip 23 is assembled from a multiplicity of scintillator pixels 34 which are arranged adjacent to one another in the longitudinal direction of the scintillator strip 23. Here, the number of scintillator pixels 34 corresponds to the number of photodiodes 12 on one of the photodiode strips 22.

Each scintillator pixel 34 is formed by a cube of scintillating material. Two adjoining scintillator pixels 34 are in this case respectively delimited—optically—from one another in the longitudinal direction by a so-called septum 35.

Each scintillator pixel 34—possibly even before the production of the scintillator strip 30—is covered by a reflector lacquer on five sides, which lacquer reflects the visible light being generated in the pixel. The side of each scintillator pixel 34 respectively not coated by reflector lacquer in each case faces the front side 36 of the scintillator strip 23 (not visible here).

This front side 36 of the scintillator strip 23 is adhesively bonded onto the front side 33 of the photodiode strip 22 in the region of the photodiodes 12 using an optically transparent adhesive. A rear side 37 of the scintillator strip 23, opposite the front side 36, thus faces away from the photodiode strip 22.

During the bonding process, the photodiode strip 22 is, using a stop, aligned in respect of the scintillator strip 23 such that respectively one scintillator pixel 34 is arranged on respectively one photodiode 12. A side face 38 adjoining the front side 36 of the scintillator strip 23 is in the process aligned substantially flush with the narrow side 33 of the photodiode strip 22. In the process, the height H_{F} of the photodiode strip 22 is greater than the height H_{S} of the scintillator strip 23. Accordingly, the narrow side 24 of the photodiode strip 22 protrudes beyond the scintillator strip 23. The height H_{S} of the scintillator strip 23 (or of a scintillator pixel 34) approximately corresponds to the width B of a photodiode 12.

FIG. 4 shows that a plurality of sensor strips 30 produced as per FIG. 3 are finally assembled to form the sensor unit 10. In the process, the individual sensor strips 30 are—again with the aid of a suitable stop—assembled to form a plate, wherein the rear side 32 of the one photodiode strip 22 is in each case adhesively bonded to the rear side 37 of the scintillator strip 23 of the adjacent sensor strip 30. In the process, the individual sensor strips 30 are, respectively in the region of the side face 38 or the narrow side 33 (on the inner side 20 of the sensor unit 10 under production), aligned approximately flush in respect of one another in order to form a planar surface. Hence, on this inner side 20, the individual scintillator pixels 34 are arranged in the scintillator 11 formed from the individual scintillator strips 23 in an array structure. In the process, the individual scintillator pixels are delimited from one another by the septa 35 in the longitudinal direction (which corresponds to the tangential direction 15); by contrast, they are basically delimited from one another by the photodiode strips 22 in the transverse direction (axial direction 14). On the outer side 21 under production, the narrow side 24 of the photodiode strips 22 protrudes beyond the scintillator strips 23 and thus offer a simple option for contacting the photodiodes 12.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combineable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, computer readable medium and computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a computer readable medium and is adapted to perform any one of the aforementioned methods when run on a computer device (a device including a processor). Thus, the storage medium or computer readable medium, is adapted to store information and is adapted to interact with a data processing facility or computer device to execute the program of any of the above mentioned embodiments and/or to perform the method of any of the above mentioned embodiments.

The computer readable medium or storage medium may be a built-in medium installed inside a computer device main body or a removable medium arranged so that it can be separated from the computer device main body. Examples of the built-in medium include, but are not limited to, rewriteable non-volatile memories, such as ROMs and flash memories, and hard disks. Examples of the removable medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A production method for a sensor unit including a scintillator with integrated photodiodes, the method comprising:
producing of a plurality of scintillator strips, each of the plurality of scintillator strips being produced from a plurality of scintillator pixels adjoining one another along one dimension;
forming a plurality of sensor strips, each of the plurality of sensor strips being formed by a longitudinal side of a respective one scintillator strip being connected to a respective one photodiode strip made of a plurality of photodiodes, likewise adjoining one another along one dimension, such that, for readout purposes, one respective photodiode being associated with a respective one of the scintillator pixels; and
interconnecting the plurality of sensor strips such that a longitudinal side of one of the plurality of sensor strips, facing away from the photodiode strip, respectively rests against a rear side of the photodiode strip of an adjacent one of the plurality of sensor strips.

2. The production method as claimed in claim 1, wherein the photodiode strip is adhesively bonded to the scintillator strip using an optically transparent adhesive in order to produce the sensor strip.

3. The production method as claimed in claim 1, wherein the individual scintillator pixels are produced in a substantially cuboid shape.

4. The production method as claimed in claim 3, wherein individual beams of scintillator material are initially lined up parallel to and at a certain distance from one another in order to produce the plurality of scintillator strips, wherein the beams are subsequently connected by filling the interspaces with at least one of a light reflecting and a light absorbing material and wherein a combination of the beams and filled interspaces is finally separated out into the individual scintillator strips in the transverse direction of the individual beams.

5. The production method as claimed in claim 3, wherein the five sides of each scintillator pixel not intended to adjoin a photodiode are provided with reflector lacquer before the sensor strip is produced.

6. The production method as claimed in claim 1, wherein the individual sensor strips are produced and assembled such that a narrow side provided for contacting the photodiodes of each photodiode strip respectively protrudes beyond the adjacent scintillator strip or strips.

7. The production method as claimed in claim 2, wherein the individual scintillator pixels are produced in a substantially cuboid shape.

8. The production method as claimed in claim 4, wherein the interspaces are filled with a polymer which is liquid at first.

9. The production method as claimed in claim 4, wherein the five sides of each scintillator pixel not intended to adjoin a photodiode are provided with reflector lacquer before the sensor strip is produced.

10. The production method as claimed in claim 8, wherein the five sides of each scintillator pixel not intended to adjoin a photodiode are provided with reflector lacquer before the sensor strip is produced.

11. The production method as claimed in claim 2, wherein the individual sensor strips are produced and assembled such that a narrow side provided for contacting the photodiodes of each photodiode strip respectively protrudes beyond the adjacent scintillator strip or strips.
